(19) United States
(12) Patent Application Publication
(10) Pub. No.: US 2015/0181731 A1
(43) Pub. Date: Jun. 25, 2015

(54) DISPLAY DEVICE AND METHOD OF MANUFACTURING THE SAME

(71) Applicants: Shanghai Tianma AM-OLED Co., Ltd., Shanghai (CN); Tianma Micro-Electronics Co., Ltd., Shenzhen (CN)

(72) Inventors: Wenjing LIN, Shanghai (CN); Yuhan Ju, Shanghai (CN)

(21) Appl. No.: 14/297,434

(22) Filed: Jun. 5, 2014

(30) Foreign Application Priority Data
Dec. 23, 2013 (CN) 201310718784.7

(51) Int. Cl. H05K 5/02; H05K 1/02; B32B 38/16; B32B 37/18; B32B 38/00; H05K 5/00; B32B 37/12

(52) U.S. Cl. CPC H05K 5/0217; H05K 5/0017; H05K 1/028; B32B 37/12; B32B 37/18; B32B 38/0036; B32B 38/0008; B32B 38/16; H05K 2201/10128; B32B 2037/1253; B32B 2038/0076; B32B 2457/20; B32B 2310/0831

(57) ABSTRACT

A flexible display device includes at least one curable adhesive layer having a hollow structure. The curable adhesive layer with the hollow structure can alleviate a stress inside the display device. The method of manufacturing a display device includes preparing a flexible display panel for displaying an image; forming a first curable adhesive layer having a hollow structure by coating curable adhesive on the flexible display panel; preparing a first flexible panel, disposing the first flexible panel on the first curable adhesive layer and curing the first curable adhesive layer. With this method, a stress inside the display device can be alleviated and a display effect can be improved.

### CROSS-REFERENCES TO RELATED APPLICATIONS

This application claims the benefit of priority to Chinese Patent Application No. 201310718784.7, filed with the Chinese Patent Office on Dec. 23, 2013 and entitled “DISPLAY DEVICE AND METHOD OF MANUFACTURING THE SAME”, the content of which is incorporated herein by reference in its entirety.

### TECHNICAL FIELD

The present invention relates to the field of display technologies, and more particularly to a display device and a method of manufacturing the same.

### BACKGROUND OF THE INVENTION

Along with constant advancement of display technologies, the emergence of flexible display devices brings great convenience to the life of people. The flexible display devices have many advantages, e.g., portability, lightweight, infrangibility, etc. A reel-like electronic reader has become possible along with the emergence of the flexible display devices.

A flexible display device, also referred to as a windable display device, is a bendable and deformable display apparatus including both a flexible display panel with a flexible substrate and a flexible function board, where display elements are arranged on the flexible substrate of the flexible display panel, and electronic elements can be arranged on the flexible function board.

In the prior art, when the flexible display panel and the flexible function board of the flexible display device are laminated together, a curable adhesive layer is coated on the entire flexible display panel and then the flexible function board is overlaid on the curable adhesive layer so that the curable adhesive layer is cured when the flexible display panel and the flexible function board are bent.

However in the prior art, the presence of the curable adhesive layer between the flexible display panel and the flexible function board may result in protrusions occurring on the surface of the bent flexible display and consequently distorting a displayed picture.

### BRIEF SUMMARY OF THE INVENTION

A display device according to an embodiment of the invention includes:

at least one curable adhesive layer having a hollow structure.

A method of manufacturing a display device according to an embodiment of the invention includes:

preparing a flexible display panel for displaying an image;

forming a first curable adhesive layer having a hollow structure by coating curable adhesive on the flexible display panel; and

preparing a first flexible panel, disposing the first flexible panel on the first curable adhesive layer and curing the first curable adhesive layer.

### BRIEF DESCRIPTION OF THE DRAWINGS

FIG. 1A to FIG. 1F are schematic plan views of curable adhesive layers according to an embodiment of the invention;

FIG. 2 is a schematic structural diagram of a display device according to an embodiment of the invention;

FIG. 3 is a schematic structural diagram of a display device according to an embodiment of the invention; and

FIG. 4 is a schematic flow chart of a method of manufacturing a display device according to an embodiment of the invention.

### DETAILED DESCRIPTION OF THE PREFERRED EMBODIMENTS

A display device according to an embodiment of the invention includes at least one curable adhesive layer having a hollow structure capable of alleviating a stress inside the display device, improving heat dissipation of the display device and prolonging the lifetime of the display device.

Embodiments of the invention will be described below in details with reference to the drawings in order to make the foregoing objects, features and advantages of the invention become more apparent.

Details will be set forth in the following description to facilitate full understanding of the invention. However the invention can be embodied in numerous other implementations than those described here, and those skilled in the art can extend the invention similarly without departing from the essence of the invention. Accordingly the invention will not be limited to the embodiments disclosed below.

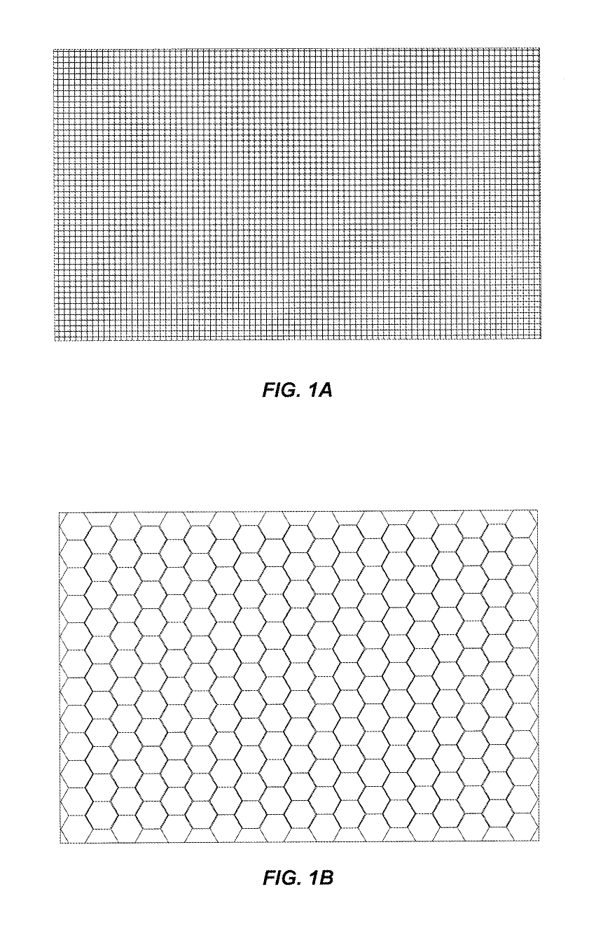

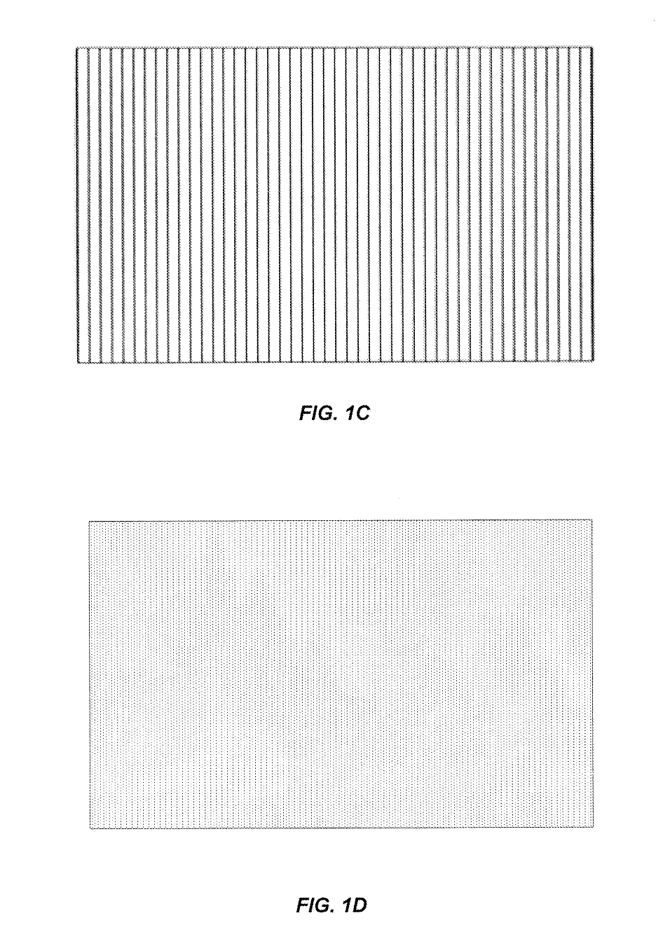

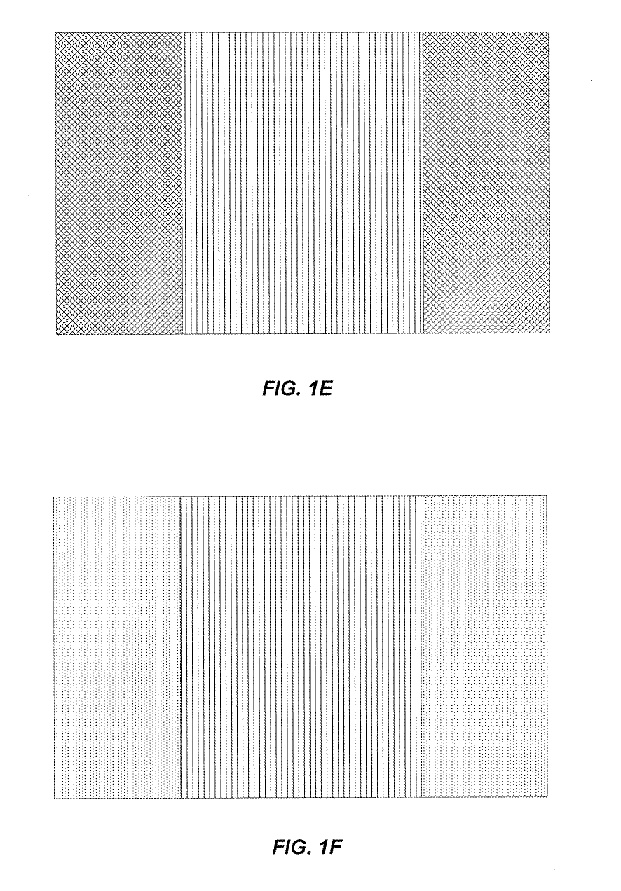

FIG. 1A to FIG. 1F each illustrate a schematic structural plan view of a curable adhesive layer included in a display device according to an embodiment of the invention, where the curable adhesive layer has a hollow structure with which a stress inside the display device can be alleviated so that the problem in the prior art, of a stress produced by a curable adhesive that cannot be released due to the curable adhesive laminated in an entire surface, can be avoided while laminating a curable adhesive layer together with another film layer or a panel. Preferably, the hollow structure can be one of a grid-like structure, a cellular structure, a strip-shaped structure and a dot-like structure or any combinations thereof.

If the curable adhesive layer has a grid-like structure, then the curable adhesive layer can be contracted by a small amount of deformation while being cured to thereby alleviate effectively a stress inside the display device and release the stress inside the display device, thus improving the lifetime of the display device and enhancing the yield thereof.

If the curable adhesive layer has a strip-shaped structure, the curable adhesive layer can come into contact with an atmosphere environment while being cured, so no bubbling or expansion will occur during curing, and the panel will not be expanded or contracted in a cold or hot environment after the display device is manufactured.

FIG. 1A illustrates a schematic structural plan view of a curable adhesive layer in a grid-like structure. The grid-like structure can be made up of a multitude of intersecting vertical and horizontal lines having their surfaces flush with the surface of the curable adhesive layer. FIG. 1B illustrates a schematic structural plan view of a curable adhesive layer in a cellular or hexagonal honeycomb-like structure. FIG. 1C illustrates a schematic structural plan view of a curable adhesive layer in a strip-shaped or bar-shaped structure having a multiple of elongated bars interspersed by a multitude of parallel grooves. In an embodiment, the top surface of the strip-shaped structure is flush with the surface of the curable adhesive layer. FIG. 1D illustrates a schematic structural plan view of a curable adhesive layer in a dot-like structure. The dot-like structure has a multitude of irregularly or regularly arranged dots that are separated from each other to form a hollow structure in the curable adhesive layer. FIG. 1E illustrates a schematic structural plan view of a curable adhesive layer in a combined grid-like and strip-shaped structure, and FIG. 1F illustrates a schematic structural plane view of a curable adhesive layer in a combined dot-like and strip-shaped structure.

It shall be noted that the curable adhesive layer according to some embodiments of the invention can include a combination of the various structures listed in FIG. 1A to FIG. 1D above. In other alternative embodiments, the curable adhesive layer according to an embodiment of the invention can have an irregular or regular hollow structure, e.g., a mesh-shaped structure, a star-like structure, a web-like structure, without departing from the scope of the invention as long as there are gaps, spaces, or holes within the curable adhesive layer.

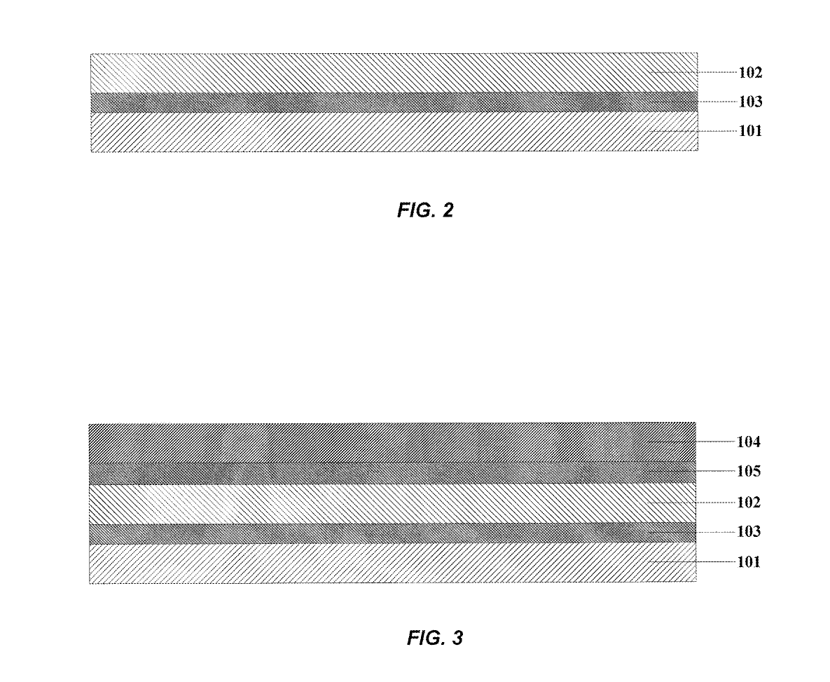

FIG. 2 illustrates a schematic structural diagram of a display device according to an embodiment of the invention. The display device includes a flexible display panel 101 for displaying an image, a first flexible panel 102 and a curable adhesive layer 103 disposed (sandwiched) between the display panel 101 and the first flexible panel 102. The curable adhesive layer 103 can include a planar structure which is one of the grid-like structure, the cellular structure, the strip-shaped structure and the dot-like structure, or any combination thereof, as described above (see FIG. 1A to FIG. 1F), or any another structures such as regular or irregular star-like, web-like, mesh-like structures, and a repeated description thereof is omitted herein for the sake of brevity.

In an embodiment, as illustrated in FIG. 3, the display device can further include a protection panel 104, where there is a curable adhesive layer 105 between the first flexible panel 102 and the protection panel 104, and the curable adhesive layer 105 can include a planar structure which is one or a combination of the grid-like structure, the cellular structure, the strip-shaped structure and the dot-like structure described above (see FIG. 1A to FIG. 1F) or in another structure, and a description thereof will not be repeated herein for reasons of brevity. The curable adhesive layer 103 may or may not be in a same structure as the curable adhesive layer 105. In an embodiment, the curable adhesive layer 103 and the curable adhesive layer 105 may have a same thickness and/or a same adhesive.

In a specific embodiment of the invention, the first flexible panel can be a touch screen panel, and the flexible display panel can be an Organic Light-Emitting Diode (OLED) panel, or a Liquid Crystal Display (LCD) panel, or an electrophoresis display panel.

A method of manufacturing a display device according to an embodiment of the invention will be described below in details.

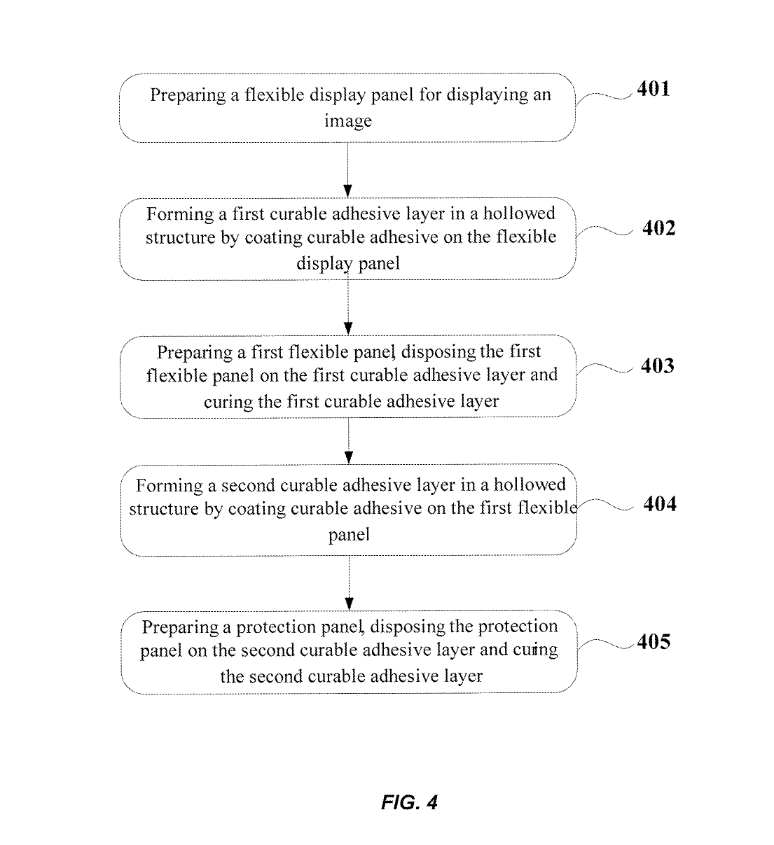

FIG. 4 is a schematic flow chart of a method of manufacturing a display device according to an embodiment of the invention. The method includes the following steps 401 to 405:

In step 401, preparing a flexible display panel for displaying an image.

The flexible display panel can be prepared by arranging display elements which are configured to display an image on a flexible substrate made of a flexible material such as plastic, where the display elements can be organic light-emitting diodes, liquid crystal display elements or electrophoresis display elements or other display elements, which will not be enumerated herein.

In step 402, forming a first curable adhesive layer having a hollow structure by coating curable adhesive on the flexible display panel.

The first curable adhesive layer can include in a planar structure which is one of a grid-like structure, a cellular structure, a strip-shaped structure and a dot-like structure, or any combination thereof. In some embodiments, the first curable adhesive layer can also include other structures as long as the hollow structure has a multitude of gaps, spaces, and/or channels in the first curable adhesive layer.

In an embodiment, a curable adhesive layer having a hollow structure is coated on the flexible display panel, and taking a grid-like structure as an example, a curable adhesive is coated on the flexible display panel to form a grid-like structure, using an adhesive dispenser.

In step 403, preparing a first flexible panel to dispose the first flexible panel on the first curable adhesive layer and to cure the first curable adhesive layer to laminate the first flexible panel and the flexible display panel.

The first curable adhesive layer can be cured through thermal curing, ultraviolet curing or air curing. In a specific embodiment, the first flexible panel can be a touch screen panel.

If the first curable adhesive layer is in a grid-like structure, then the first curable adhesive layer can be contracted by a small amount of deformation while being cured to thereby alleviate effectively a stress inside the display device and release the stress inside the display device, thus improving lifetime of the display device and enhancing the yield thereof.

The structure as illustrated in FIG. 2 can be obtained after the steps 401 to 403 are performed.

In an embodiment, the method further includes the following steps 404 and 405 may further include after the step 403 the following steps:

In step 404, forming a second curable adhesive layer having a second hollow structure by coating curable adhesive on the first flexible panel.

The second curable adhesive layer can include a planar structure which is one of a grid-like structure, a cellular structure, a strip-shaped structure and a dot-like structure, a combination of thereof, or other structures, e.g., a regular or irregular meshed, star-, or web-like structure.

A curable adhesive layer having a hollow structure is coated on the first flexible panel, and taking a strip-shaped structure as an example, curable adhesive is coated on the first flexible panel to form a strip-shaped structure, using an adhesive dispenser.

In step 405, preparing a protection panel, to dispose the protection panel on the second curable adhesive layer and to cure the second curable adhesive layer to laminate the protection panel and the first flexible panel.

The second curable adhesive layer can be cured through thermal curing, ultraviolet curing or air curing. In a preferred embodiment, the protection panel can be a flexible transparent panel.

If the second curable adhesive layer includes a strip-shaped structure, then the second curable adhesive layer can come into contact with an atmosphere environment while being cured, so no bubbling or expansion will occur during curing, and the panel will not be expanded or contracted in a cold or hot environment after the display device is manufactured.

The structure as illustrated in FIG. 3 can be obtained after the steps 401 to 405 are performed.

In the solution according to any one embodiment of the invention, a curable adhesive layer having a hollow structure is coated between panels of a display device so that it is capable of alleviating a stress inside the display device, improving heat dissipation of the display device and prolonging lifetime of the display device. Moreover, in the solution according to any one embodiment of the invention, the curable adhesive layer with the hollow structure can be cured without bending the display device to thereby enhance the yield in a manufacturing process.

While preferred embodiments of the invention have been described in detail, various modifications can be made by those skilled in the art. Therefore, the embodiments of the present invention should not be limited to the particular forms as illustrated. The appended claims are intended to be construed as encompassing the preferred embodiments and all the modifications and variations coming into the scope of the invention.

Evidently those skilled in the art can make various modifications and variations to the invention without departing from the essence and scope of the invention. Thus the invention is also intended to encompass these modifications and variations thereto so long as the modifications and variations come into the scope of the claims appended to the invention and their equivalents.

What is claimed is:

1. A display device comprising:
a first curable adhesive layer having a hollow structure.

2. The display device of claim 1, wherein the hollow structure is one of a grid-like structure, a cellular structure, a strip-shaped structure, a dot-like structure, or a combination thereof.

3. The display device of claim 1, further comprising:
a flexible display panel and a first flexible panel, wherein the first curable adhesive layer is disposed between the flexible display panel and the first flexible panel.

4. The display device of claim 3, wherein:
the first flexible panel is a touch screen panel.

5. The display device of claim 3, wherein:
the flexible display panel is an organic light-emitting diode panel, a liquid crystal display panel, or an electrophoresis display panel.

6. The display device of claim 3, further comprising a protection panel, and a second adhesive layer, the second adhesive layer being disposed between the first flexible panel and the protection panel.

7. The display device of claim 2, further comprising:
a flexible display panel and a first flexible panel, wherein the first curable adhesive layer is disposed between the flexible display panel and the first flexible panel.

8. The display device of claim 7, wherein:
the first flexible panel is a touch screen panel.

9. The display device of claim 7, wherein:
the flexible display panel is an organic light-emitting diode panel, a liquid crystal display panel, or an electrophoresis display panel.

10. The display device of claim 7, further comprising a protection panel, and a second adhesive layer, the second adhesive layer being disposed between the first flexible panel and the protection panel.

11. A method of manufacturing a display device comprising:
preparing a flexible display panel for displaying an image;
forming a first curable adhesive layer having a hollow structure by coating a first curable adhesive on the flexible display panel;
preparing a first flexible panel;
disposing the first flexible panel on the first curable adhesive layer; and
curing the first curable adhesive layer.

12. The method of claim 11, further comprising:
forming a second curable adhesive layer having a hollow structure by coating a second curable adhesive on the first flexible panel;
preparing a protection panel;
disposing the protection panel on the second curable adhesive layer; and
curing the second curable adhesive layer.

13. The method of claim 11, wherein the first curable adhesive layer is cured through one of thermal curing, ultraviolet curing or air curing.

14. The method of claim 12, wherein the second curable adhesive layer is cured through one of thermal curing, ultraviolet curing or air curing.

15. The method of claim 11, wherein:
the first flexible panel is a touch screen panel.

16. The method of claim 12, wherein:
the first flexible panel is a touch screen panel.

17. The method of claim 12, wherein the first curable adhesive layer and the second curable adhesive layer have a same thickness.
